(19) United States
(12) Patent Application Publication
(10) Pub. No.: US 2017/0170150 A1
(43) Pub. Date: Jun. 15, 2017

(54) SEMICONDUCTOR MODULE AND SEMICONDUCTOR DEVICE

(71) Applicant: Kabushiki Kaisha Toshiba, Minato-ku (JP)

(72) Inventors: Tomohiro IGUCHI, Kawasaki (JP); Akihiro Sasaki, Shinagawa (JP); Tetsuya Yamamoto, Sagamihara (JP); Takashi Togasaki, Yokohama (JP)

(73) Assignee: Kabushiki Kaisha Toshiba, Minato-ku (JP)

(21) Appl. No.: 15/377,145

(22) Filed: Dec. 13, 2016

(30) Foreign Application Priority Data
Dec. 14, 2015 (JP) 2015-242995

(51) Int. Cl. H01L 25/07; H01L 23/31; H01L 23/492; H01L 23/498; H01L 23/50; H01L 23/00

(52) U.S. Cl. CPC H01L 25/072; H01L 23/50; H01L 24/29; H01L 24/32; H01L 24/33; H01L 24/30; H01L 23/492; H01L 23/49805; H01L 23/3121; H01L 2224/29139; H01L 2924/014; H01L 2224/32245; H01L 2224/33181; H01L 2224/30181

(57) ABSTRACT

A semiconductor module according to an embodiment has first and second wiring portions, first semiconductor devices and second semiconductor devices. The second wiring portion is provided to oppose the first wiring portion. The third wiring portion is provided to oppose the first wiring portion. The first semiconductor devices are provided between the first wiring portion and the second wiring portion. Each of the first semiconductor devices has a first switching element, and an input terminal or an output terminal of the first switching element is electrically connected with the first wiring portion. The second semiconductor devices are provided between the first wiring portion and the third wiring portion. Each of the second semiconductor devices has a second switching element, and an output or input terminal of the second switching element is electrically connected with the first wiring portion in a manner contrary to the first switching element.

### CROSS-REFERENCE TO RELATED APPLICATION

This application is based upon and claims the benefit of priority from the prior Japanese Patent Application No. 2015-242995, filed on Dec. 14, 2015, the entire contents of which are incorporated herein by reference.

### FIELD

Embodiments described herein relate generally to a semiconductor module and a semiconductor device.

### BACKGROUND

In a field of a power converting apparatus such as an inverter device, a semiconductor module in which plural kinds of semiconductor elements are provided on one substrate is used. In such a semiconductor module, it is desired to have a structure which is as simple as possible in order to achieve miniaturization, enlargement of scale, reduction in inductance, reduction in cost etc.

### BRIEF DESCRIPTION OF THE DRAWINGS

FIG. 1 is a schematic top view which illustrates a semiconductor module having semiconductor devices according to a first embodiment.

FIG. 2 is a side view of the semiconductor module seen from an A-A plane in FIG. 1.

FIG. 3 is a sectional view of the semiconductor module taken along a B-B plane in FIG. 1.

FIG. 4 is a circuit diagram of each semiconductor device.

FIG. 5A is an enlarged and schematic view of a section of the semiconductor module taken along a C-C plane in FIG. 1.

FIG. 5B is an enlarged and schematic view of a section of the semiconductor module taken along a D-D plane in FIG. 1.

FIG. 6A is an enlarged and schematic view of a section of the semiconductor module taken along an E-E plane in FIG. 1.

FIG. 6B is an enlarged and schematic view of a section of the semiconductor module taken along an F-F plane in FIG. 1.

FIG. 7 is a schematic view which illustrates an inverter device using the semiconductor module.

FIG. 8A is a schematic top view which illustrates a semiconductor module according to a comparative example.

FIG. 8B is a sectional view of the semiconductor module taken along a G-G plane in FIG. 8A.

FIG. 8C is a sectional view of the semiconductor module taken along an H-H plane in FIG. 8A.

FIG. 9 is a schematic sectional view which illustrates a semiconductor device according to another embodiment.

### DETAILED DESCRIPTION

A semiconductor module according to an embodiment has first and second wiring portions, first semiconductor devices and second semiconductor devices. The second wiring portion is provided to oppose the first wiring portion. The third wiring portion is provided to oppose the first wiring portion and apart from the second wiring portion. The first semiconductor devices are provided between the first wiring portion and the second wiring portion and are electrically connected with the first wiring portion and the second wiring portion respectively. Each of the first semiconductor devices has a first switching element, and an input or output terminal of the first switching element is electrically connected with the first wiring portion. The second semiconductor devices are provided between the first wiring portion and the third wiring portion and are electrically connected with the first wiring portion and the second wiring portion respectively. Each of the second semiconductor devices has a second switching element, and an output or input terminal of the second switching element is electrically connected with the first wiring portion in a connecting manner contrary to the first switching element.

Hereinafter, further embodiments will be described with reference to the drawings. In the drawings, the same reference numerals denote the same or similar portions respectively.

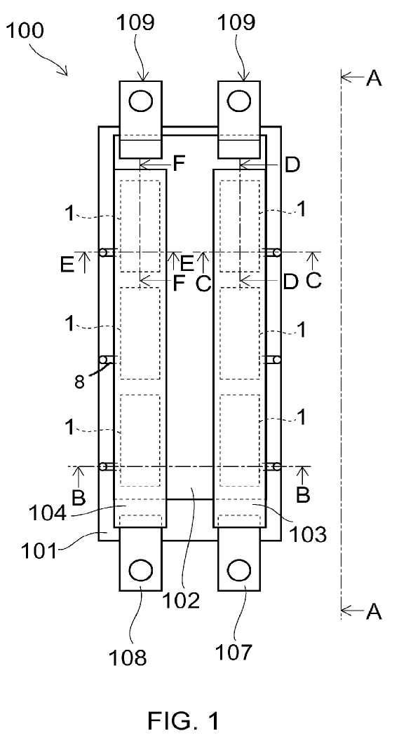

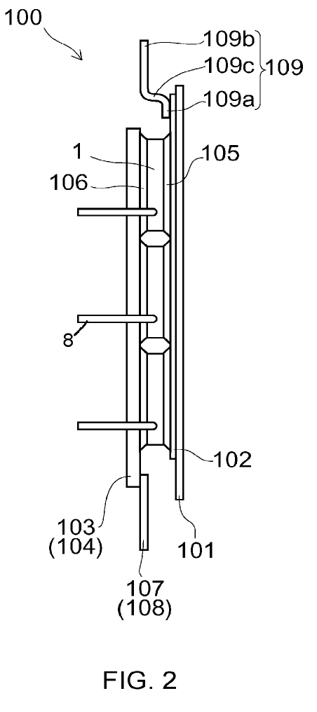

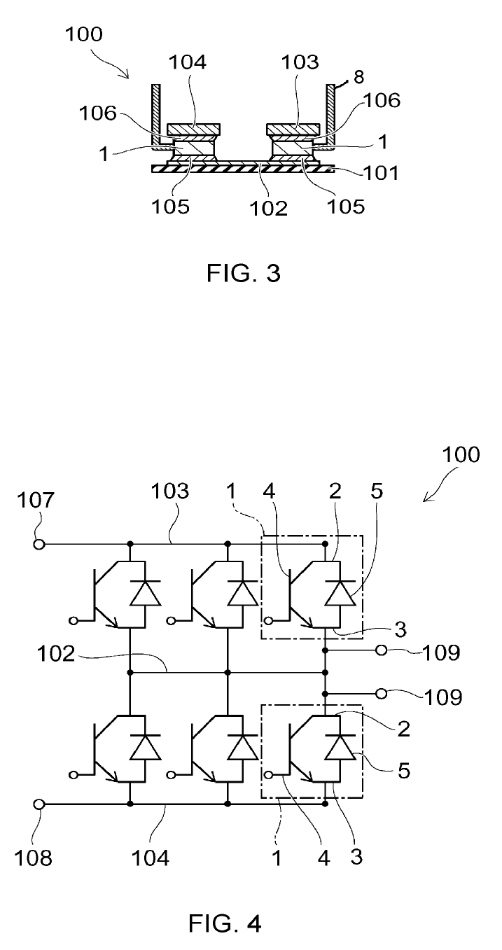

A semiconductor module having semiconductor devices according to a first embodiment will be described with reference to FIGS. 1 to 4. FIG. 1 is a schematic top view which illustrates a semiconductor module having a plurality of semiconductor devices according to a first embodiment. FIG. 2 is a side view of the semiconductor module seen from an A-A plane in FIG. 1. FIG. 3 is a sectional view of the semiconductor module taken along a B-B plane in FIG. 1. In FIG. 3, an internal structure of each semiconductor device is omitted to avoid complexity. FIG. 4 is a circuit diagram of each semiconductor device.

As shown in FIGS. 1 to 4, a semiconductor module 100 has a substrate 101, a wiring portion 102 as a first wiring portion, a wiring portion 103 as a second wiring portion, a wiring portion 104 as a third wiring portion, joining portions 105, joining portions 106, a terminal 107, a terminal 108, two terminals 109, and six semiconductor devices 1. The joining portions 105 and 106 do not appear in FIG. 1.

The substrate 101 is flat-plate-shaped and is formed of an insulating material. The substrate 101 can be formed of an inorganic material such as aluminum oxide or aluminum nitride i.e. a ceramic, or an organic material such as paper phenol or glass epoxy.

The substrate 101 may be a metal plate having a surface covered with an insulator. When such a metal plate having a surface covered with an insulator is used, the insulator may be composed of an organic material or an inorganic material.

When the substrate 101 is formed of an organic material such as glass epoxy, manufacturing cost of the semiconductor module 100 can be reduced. When the semiconductor device 1 have a characteristic of producing much heat, it is desirable that the substrate 101 is formed of a material having a high thermal conductivity in order to enhance heat dissipation. Specifically, it is desirable to form the substrate 101 of a ceramic such as aluminum oxide or aluminum nitride, or a metal plate having a surface covered with an insulator.

The substrate 101 is not always necessary and may be provided when needed. The substrate 101 can be omitted when the rigidity of the wiring portion 102 is high. When a metal plate having a surface covered with an insulator is not used, an insulating part such as an insulating sheet may be provided on a device, for example, an inverter device in which such a semiconductor module is provided, and the semiconductor module may be arranged on the insulating part.

The wiring portion 102 is provided on one main surface of the substrate 101. The planar shape of the wiring portion 102 can be the same as that of the substrate 101. For example, when the planar shape of the substrate 101 is a rectangle, the planar shape of the wiring portion 102 can also be a rectangle. The planar dimensions of the wiring portion 102 can also be the same as those of the substrate 101 or smaller. The wiring portion 102 can be provided on an entire area of a surface of the substrate 101.

The wiring portion 102 is formed of a conductive material. The wiring portion 102 can be formed of copper, a copper alloy, aluminum, an aluminum alloy etc. The wiring portion 102 can be formed on one main surface of the substrate 101 using a plating method etc. When the wiring portion 102 is formed using a plating method, the thickness of the wiring portion 102 can be made larger than that of a general wiring pattern. The thickness dimension of the wiring portion 102 can be 100 micrometers or more. Reduction of the impedance of the wiring portion 102 can be achieved by enlarging the thickness of the wiring portion 102. The wiring portion 102 may be a metal plate. When the wiring portion 102 is a metal plate, the substrate 101 can be omitted since the rigidity of the wiring portion 102 is high. The impedance of the wiring portion 102 can be further reduced by forming the wiring portion 102 with a metal plate.

The wiring portion 103 is a rectangle. The wiring portion 103 opposes the wiring portion 102. The planar shape of the wiring portion 103 can be a rectangle. In this case, a long side of the wiring portion 103 can be parallel to a long side of the wiring portion 102. The planar dimensions of the wiring portion 103 are smaller than those of the wiring portion 102. The wiring portion 103 is formed of a conductive material. The wiring portion 103 can be a metal plate. The wiring portion 103 can be formed of copper, copper alloy, aluminum, aluminum alloy etc. The wiring portion 103 can be a bus bar. A surface of the wiring portion 103 may be plated with nickel etc.

The wiring portion 104 is a rectangle. The wiring portion 104 opposes the wiring portion 102. The planar shape of the wiring portion 104 can be a rectangle. In this case, a long side of the wiring portion 104 can be parallel to the long side of the wiring portion 103. The planar shape and the planar dimensions of the wiring portion 104 can be the same as those of the wiring portion 103. The wiring portion 104 is formed of a conductive material. The material of the wiring portion 104 can be the same as that of the wiring portion 103. The wiring portion 104 can be a bus bar. A surface of the wiring portion 104 may be plated with nickel etc. The wiring portions 103, 104 are arranged to oppose the wiring portion 102. The wiring portions 102 to 104 are provided to oppose the plurality of semiconductor devices.

As shown in FIGS. 2 and 3, the joining portions 105 are provided between the wiring portion 102 and the semiconductor devices 1, respectively. Each joining portion 105 connects the wiring portion 102 to each semiconductor device 1 electrically and mechanically. The joining portions 105 can be formed of a conductive joining material such as a solder or a silver paste.

The joining portions 106 are provided between the wiring portions 103, 104 and the semiconductor devices 1 respectively. The joining portions 106 connect the wiring portions 103, 104 and the semiconductor devices 1 electrically and mechanically, respectively.

The joining portions 106 can be formed of a conductive joining material such as a solder or a silver paste. The material of the joining portions 106 can be the same as the material of the joining portions 105 or the material different from the material of the joining portions 105.

The terminal 107 is a rectangle. The terminal 107 extends in a direction in which the wiring portion 103 extends. One end portion of the terminal 107 is provided on the wiring portion 103. The other end portion of the terminal 107 i.e. an end portion of the terminal 107 which opposes the wiring portion 103 is provided outside the substrate 101 in a planar view. The other end portion of the terminal 107 may be provided inside the substrate 101 in a planar view. A circular hole for wiring can be provided in the terminal 107 so that the circular hole may be positioned near the other end portion of the terminal 107 as shown in FIG. 1.

The terminal 107 is connected to the wiring portion 103 electrically and mechanically. The terminal 107 can be welded to the wiring portion 103, be brazed to the wiring portion 103, be soldered to the wiring portion 103, or be attached to the wiring portion 103 with a screw. The terminal 107 and the wiring portion 103 may be made of a single body. The wiring portion 103 can be extended to form the terminal 107.

The terminal 107 is formed of a conductive material. The terminal 107 can be a metal plate. The terminal 107 can be formed of copper, copper alloy, aluminum, aluminum alloy etc. The material of the terminal 107 can be the same as that of the wiring portion 103.

The terminal 108 is rectangle. The terminal 108 extends in a direction in which the wiring portion 104 extends. One end portion of the terminal 108 is provided on the wiring portion 104. The other end portion of the terminal 108 i.e. an end portion of the terminal 108 which opposes the wiring portion 104 is provided outside the substrate 101 in a planar view. The other end portion of the terminal 108 may be provided inside the substrate 101 in a planar view. A circular hole for wiring can be provided in the terminal 107 so that the circular hole may be positioned near the other end portion of the terminal 107 as shown in FIG. 1.

The terminal 108 is connected to the wiring portion 104 electrically and mechanically. The terminal 108 can be welded to the wiring portion 104, be brazed to the wiring portion 104, be soldered to the wiring portion 104, or be attached to the wiring portion 104 with a screw. The terminal 107 and the wiring portion 103 may be made of a single body. The wiring portion 103 can be extended to form the terminal 107. The terminal 108 is formed of a conductive material. The material of the terminal 108 may be the same as that of the terminal 107.

Each of the terminals 109 has a flat plate portion 109a, another flat plate portion 109b, and a bending portion 109c as shown in FIG. 2. One end portion of the bending portion 109c is connected to one end portion of the flat plate portion 109a. The other end portion of the bending portion 109c is connected to one end portion of the flat plate portion 109b. The flat plate portion 109b is provided in parallel to the flat plate portion 109a. The bending portion 109c extends in a direction which intersects the flat plate portion 109a and the flat plate portion 109b. The flat plate portion 109a, the flat plate portion 109b and the bending portion 109c may be formed of a single body. The terminals 109 can be formed by bending a rectangular plate in a shape of a crank.

The flat plate portion 109a is connected to the wiring portion 102 electrically and mechanically. The flat plate portion 109a can be welded to the wiring portion 102, be brazed to the wiring portion 102, be soldered to the wiring portion 102, or be attached to the wiring portion 102 with a screw. The other end portion of the flat plate portion 109b which opposes the bending portion 109c is provided outside the substrate 101 in a planar view. The other end portion of the flat plate portion 109b may be provided inside substrate 101 in a planar view.

A circular hole for wiring can be provided in the flat plate portion 109b near the other end portion of the flat plate portion 109b, as shown in FIG. 1. The distance between the flat plate portion 109b and the substrate 101 can be the same as the distance between the terminal 107 or the terminal 108 and the substrate 101. The terminal 109, i.e., the flat plate portion 109a, the flat plate portion 109b and the bending portion 109c are formed of a conductive material. The material of the terminal 109 can be the same as the material of the terminals 107, 108.

The terminals 109 and the wiring portion 102 may be formed of a single body. For example, when the wiring portion 102 is a metal plate, the terminal 109 can be formed by bending an end portion of the wiring portion 102.

In the above embodiment, two terminals 109 are provided, but one or more than two terminals 109 may be provided. In the above embodiment, a rectangular terminal 107, a rectangular terminal 108 and crank-shaped terminals 109 are used, but the shapes of these terminals may be changed appropriately. The shapes of the terminals 107, 108 and 109 can be changed according to a positional relationship etc. with a device or an apparatus arranged in the exterior of the semiconductor module 100.

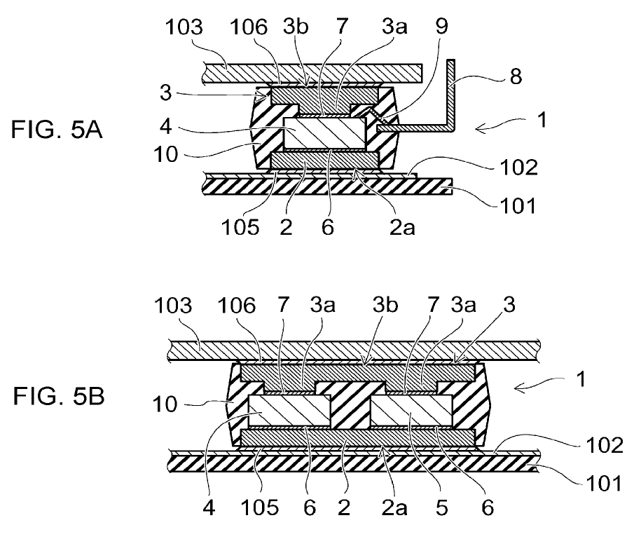

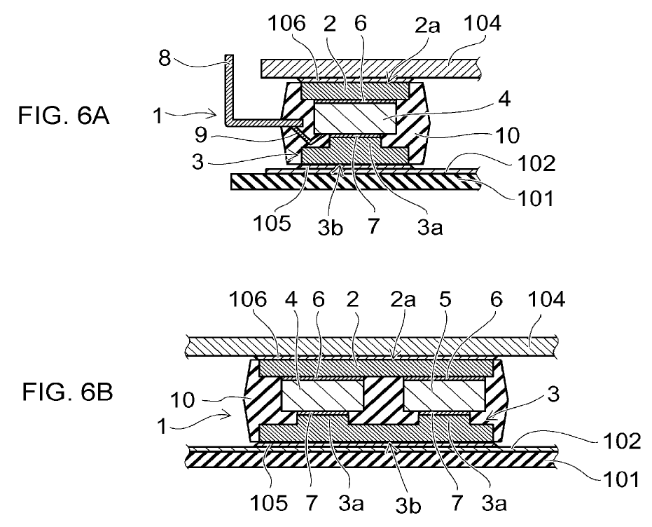

A connected state and a structure of each semiconductor device 1 will be explained with reference to FIG. 4, FIGS. 5A and 5B, and FIGS. 6A and 6B. FIGS. 5A, 5B, 6A and 6B are enlarged and schematic views of sections of the semiconductor module taken along a C-C plane, a D-D plane, an E-E plane and an F-F plane in FIG. 1, respectively.

Each semiconductor device 1 has an electrode 2 as a first electrode, an electrode 3 as a second electrode, a switching element 4, a rectifying element 5, two joining portions 6, two joining portions 7, a lead terminal 8, a wiring 9 and a sealing portion 10. The electrode 2 is flat-plate-shaped. The planar shape of the electrode 2 can be a rectangle. The electrode 2 is formed of a conductive material. The electrode 2 can be formed of copper, copper alloy, aluminum, aluminum alloy etc. A main surface 2a of the electrode 2 which is positioned at a side opposite to a side of both of the switching element 4 and the rectifying element 5 is arranged on the wiring portion 102 via the joining portion 105.

The electrode 3 opposes the electrode 2. A main surface 3b of the electrode 3 which is positioned at a side opposite to a side of both of the switching element 4 and the rectifying element 5 is provided on the wiring portion 103 or the wiring portion 104 via the joining portion 105. The planar shape of the electrode 3 can be a rectangle. A plurality of convex portions 3a is formed on a portion of the electrode 3 which opposes both of the switching element 4 and the rectifying element 5. The planar dimensions of each convex portion 3a are smaller than the planar dimensions of the switching element 4. A space for arranging the wiring 9 is provided in a side direction of the convex portion 3a. The convex portions 3a are provided in order to prevent short circuit between the electrode 3 and the wiring 9. For the purpose of preventing short circuit, the convex portions 3a may be projected at least toward the switching element 4. The electrode 3 is formed of a conductive material. The electrode 3 can be formed of copper, copper alloy, aluminum, aluminum alloy etc. The material of the electrode 3 may be the same as that of the electrode 2, or different from that of the electrode 2.

The switching element 4 is provided between the electrode 2 and the electrode 3. The switching element 4 may be an insulated gate bipolar transistor, a field effect transistor, a gate turn-off thyristor, a bipolar transistor etc. The kind of the switching element 4 is not limited to these elements. According to the embodiment, IGBT is used as the switching element 4.

The rectifying element 5 is formed between the electrode 2 and the electrode 3. The rectifying element 5 is connected in parallel with the switching element 4 via the electrode 2 and the electrode 3. The rectifying element 5 may be a diode.

One of the joining portions 6 is provided between the electrode 2 and the switching element 4, and the other of the joining portions 6 is provided between the electrode 2 and the rectifying element 5. The joining portions 6 connect the switching element 4 and rectifying element 5 with the electrode 2 electrically and mechanically. The joining portions 6 can be formed of a conductive joining material such as solder or a silver paste.

One of the joining portions 7 is provided between one of the convex portions 3a of the electrode 3 and the switching element 4, and the other of the joining portions 7 is provided between another one of the convex portions 3a and the rectifying element 5. The joining portions 7 connect the switching element 4 and the rectifying element 5 with the electrode 3 electrically and mechanically. The joining portions 7 can be formed of a conductive joining material such as solder or a silver paste. The material of the joining portions 7 may be same as that of the joining portions 6 or different from that of the joining portions 6. When the thicknesses of the switching element 4 and the rectifying element 5 are different, the thickness of the joining portions 6 and the joining portions 7 can be adjusted appropriately to match the switching element 4 and the rectifying element 5 with the heights of the electrodes 2, 3. In order to match the switching element 4 and the rectifying element 5 with the heights of the electrodes 2, 3, a conductive spacer (not illustrated) may be arranged between the switching element 4 or the rectifying element 5 and one of the convex portions 3a of the electrode 3.

The lead terminal 8 is line-shaped. One end portion of the lead terminal 8 is buried in the interior of the sealing portion 10 and is held at an approximately central position in a thickness direction of the sealing portion 10.

The lead terminal 8 may have a shape bending toward a side of the wiring portions 103, 104. The lead terminal 8 may be a shape of an L character. The lead terminal 8 is formed of a conductive material. The lead terminal 8 can be formed of copper, copper alloy, aluminum, aluminum alloy etc.

The wiring 9 may be a line-shaped body of a metal such as gold, copper or aluminum. The wiring 9 is provided between the lead terminal 8 and the switching element 4. One end portion of the wiring 9 is electrically connected to the lead terminal 8. The other end portion of the wiring 9 is electrically connected to a gate or a base of the switching element 4 which is a control terminal of the switching element 4. The wiring 9 may be joined to the lead terminal 8 and the gate or the base of the switching element 4 using a wire bonding method.

The sealing portion 10 seals the switching element 4 and the rectifying element 5 between the electrode 2 and the electrode 3 from a side direction. The sealing portion 10 is formed of an insulating material such as an epoxy resin. The sealing portion 10 may be formed using a transfer-molding method.

As shown in FIG. 4, in the semiconductor device 1, the rectifying element 5 is connected in parallel with the switching element 4. For example, a collector which is one of input and output terminals of the switching element 4, and a cathode of the rectifying element 5 are electrically connected via the electrode 2. An emitter which is the other of the input and output terminals of the switching element 4, and an anode of the rectifying element 5 are electrically connected via the electrode 3. The semiconductor device 1 having such a structure can be used as an arm of an inverter circuit, for example.

In the semiconductor module 100, three of the semiconductor devices 1 are connected in parallel with one another via the wiring portion 102 and the wiring portion 103, and the remaining three of the semiconductor devices 1 are connected in parallel with one another via the wiring portion 102 and the wiring portion 104. In this case, as shown in FIG. 1, the former three semiconductor devices 1 are arranged in order along a direction in which the wiring portion 103 extends. The remaining three semiconductor devices 1 are arranged in order along a direction in which the wiring portion 104 extends. The number of the semiconductor devices 1 which are connected in parallel may be changed appropriately depending on a current value etc. to be required. The number of the semiconductor devices 1 which are connected in parallel may be two or more.

A leg of an inverter circuit can be composed of such semiconductor devices 1. Six semiconductor devices 1 are used to compose an inverter device for a three-phase motor,.

In the semiconductor module 100, part of the semiconductor devices 1 as the first semiconductor devices which are arranged between the wiring portion 102 and the wiring portion 103 face to the substrate 101 in a direction contrary to the remaining semiconductor devices 1 as are the second semiconductor devices which are arranged between the wiring portion 102 and the wiring portion 104. In other words, the direction of the input terminals or the output terminals of the first semiconductor devices connected to the electrodes 2 are contrary to that of the second semiconductor devices connected to the electrodes 2. For example, as shown in FIG. 4, in each semiconductor device 1 which is arranged between the wiring portion 102 and the wiring portion 103, the emitter of the switching element 4 and the anode of the rectifying element 5 are electrically connected with the wiring portion 102. On the other hand, in each semiconductor device 1 which is arranged between the wiring portion 102 and the wiring portion 104, the collector of the switching element 4 and the cathode of the rectifying element 5 are electrically connected with the wiring portion 102.

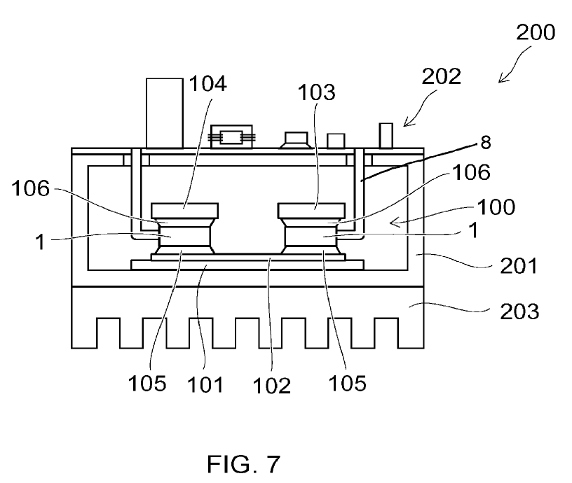

FIG. 7 is a schematic view showing an example in which a semiconductor module 100 is applied to an inverter device. As shown in FIG. 7, an inverter device 200 has a semiconductor module 100 which is shown in FIG. 1, a case 201, a driving circuit 202 and a cooling portion 203. A plus terminal of a direct-current power supply (not shown) is connected to a terminal 107 of the semiconductor module 100. A minus terminal of the direct-current power supply is connected to a terminal 108 of the semiconductor module 100.

The case 201 is rectangular-parallelepiped-shaped. The semiconductor module 100 is arranged in the interior of the case 201. The case 201 may be formed of an insulating material such as resin.

The driving circuit 202 is provided on an outer surface of the case 201. The driving circuit 202 is arranged to oppose a side of the substrate 101 of the semiconductor module 100, above the semiconductor module 100 for example. The driving circuit 202 applies a control signal to the gate or base of each switching element 4 via the lead terminal 8, for example. The semiconductor module 100 converts a direct-current electric power supplied from the direct-current power supply into a desired alternate-current electric power, based on a control signal from the driving circuit 202. The obtained alternate-current electric power is supplied to an apparatus (not illustrated) which is connected to the inverter device 200, a three-phase motor for example. The cooling portion 203 is provided on an outer surface of the case 201. The cooling portion 203 is provided on a side of the substrate 101 of the semiconductor module 100, below the semiconductor module 100 for example. The cooling portion 203 may be heat-radiating fins. As described above, the lead terminals 8 are L-character-shaped. Thus, the lead terminals 8 can be connected with the driving circuit 202 which are provided above the semiconductor module 100 easily.

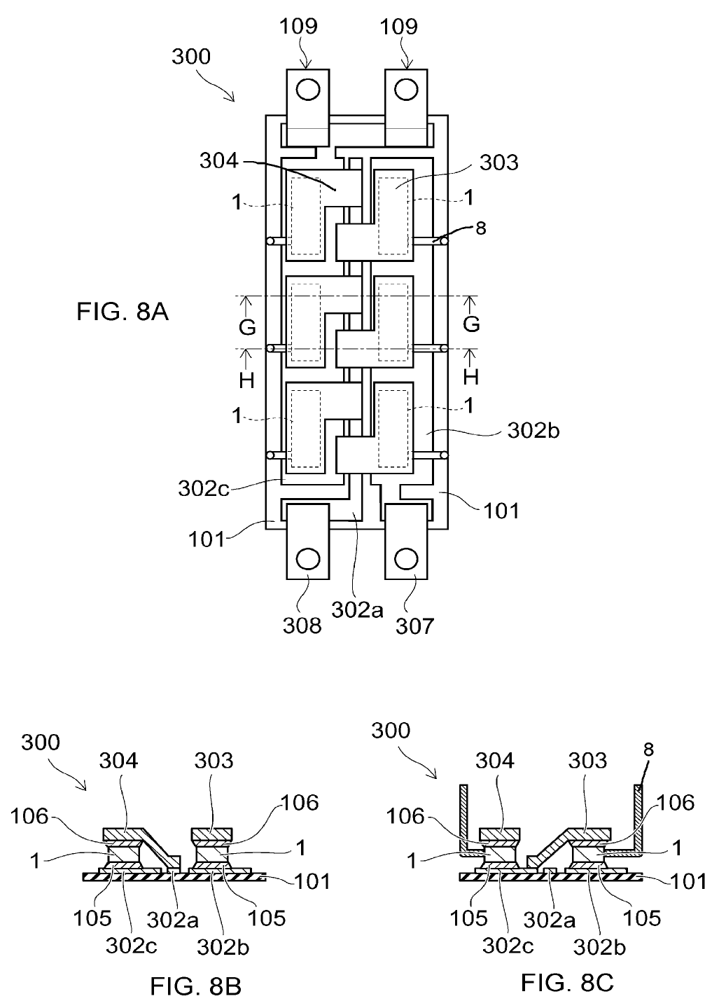

FIGS. 8A to 8C are schematic views which illustrate a semiconductor module according to a comparative example. FIG. 8A is a schematic top view of the semiconductor module. FIG. 8B is a sectional view of the semiconductor module taken along a G-G plane in FIG. 8A. FIG. 8C is a sectional view of the semiconductor module taken along an H-H plane in FIG. 8A.

As shown in FIGS. 8A to 8C, a semiconductor module 300 is provided with a substrate 101, a wiring portions 302a to 302c, a wiring portion 303, a wiring portion 304, joining portions 105, joining portions 106, a terminal 307, a terminal 308, terminals 109, and semiconductor devices 1.

The wiring portions 302a to 302c are provided on one main surface of the substrate 101. The wiring portions 302a to 302c are patterned wirings. The wiring portions 303, 304 can be formed by bending a L-character-shaped metal plate into a shape of a crank. The terminals 307, 308 can be formed by bending a rectangular metal plate into a shape of a crank.

The semiconductor devices 1 of the comparative example are formed on the wiring portions 302b, 302c via the joining portions 105, respectively. The semiconductor devices 1 are connected in the same direction to the substrate 101. Specifically, all of the semiconductor devices 1 of the comparative example are mounted on the wiring portions 302b, 302c so that a collector of each switching element and a cathode of each rectifying element which compose a circuit similar to that shown in FIG. 4 may be positioned on a side of the substrate 101. The connections shown in FIG. 4 are obtained by the wiring portions 302a, 303 and 304.

Thus, the structure of the semiconductor module 300 of the comparative example becomes complicated. Further, the width of the wiring portion 302a which extends between one row of the semiconductor devices 1 and the other row of the semiconductor devices 1 becomes narrow, and the inductance may increase. In this case, the inductance can be small by enlarging the width of the wiring portion 302a, but it results in causing enlargement of the semiconductor module 300. On the other hand, when the semiconductor module 300 is made in a predetermined size, the number of the semiconductor devices to be arranged decreases, and enlargement of scale may not be achieved.

On the other hand, in the semiconductor module 100 according to the embodiment, part of the semiconductor devices 1 as the first semiconductor devices which are arranged between the wiring portion 102 and the wiring portion 104 face to the substrate 101 in a direction contrary to the remaining semiconductor devices 1 as the second semiconductor devices which are arranged between the wiring portion 102 and the wiring portion 103. The input or output terminals of the first semiconductor devices that are connected to the electrodes 2 are contrary to the output or input terminals of the second semiconductor devices. Further, the connections shown in FIG. 4 are obtained by the wiring portions 102, 103 104 which have shapes different from those of the wiring portions 302a, 303 and 304 of the comparative example.

In the embodiment, the wiring portion 102 does not always need to be a patterned wiring, but may be a mere film body of a rectangular. Further, the wiring portion 103 and the wiring portion 104 can be formed of a rectangular metal plate. Accordingly, a semiconductor module 100 which has a simple structure is obtained. Since the cross-sectional area of the wiring portion 102 can be enlarged in a thickness direction with ease, the inductance can be reduced. Since the wiring portion 102 does not always need to be a patterned wiring, the distance between one row of the semiconductor devices 1 and the other row of the semiconductor devices 1 can be shortened. Thus, miniaturization and enlargement of scale of the semiconductor module 100 can be attained.

Part of the semiconductor devices 1 which are arranged between the wiring portions 102, 104 face to the substrate 101 in a direction contrary to the others of the semiconductor devices 1 which are arranged between the wiring portions 102, 103. Accordingly, part of the lead terminals 8 of the semiconductor devices 1 which are provided between the wiring portions 102, 104 bend in a direction contrary to the others of the lead terminals 8 which are provided between the wiring portions 102, 103. In this case, the end portions of these lead terminals 8 are held at an approximately center position in a thickness direction of the sealing portion 10. Thus, when the lead terminals 8 are made by bending, it is possible to use the same metallic mold. Further, the lead terminals 8 can be made by bending using a metallic mold which is employed when the sealing portion 10 is formed.

Heat produced in each switching elements 4 and each rectifying elements 5 is mainly transmitted to a side of the substrate 101. In this case, as shown in FIGS. 5A, 5B, in part of the semiconductor devices 1 which are provided between the wiring portions 102, 103, the corresponding electrodes 2 are provided on a side of the substrate 101. On the other hand, as shown in FIGS. 6A, 6B, in the others of the semiconductor devices 1 which are provided between the wiring portions 102, 104, the corresponding electrodes 3 are provided on a side of the substrate 101. In addition, the electrodes 2 are plate-shaped and the electrodes 3 have the convex portions 3a respectively. Accordingly, the heat resistance of each electrode 2 differs from that of each electrode 3 so that uniformity of temperature distribution may not be obtained in the semiconductor module 100. This is improved in the following embodiment.

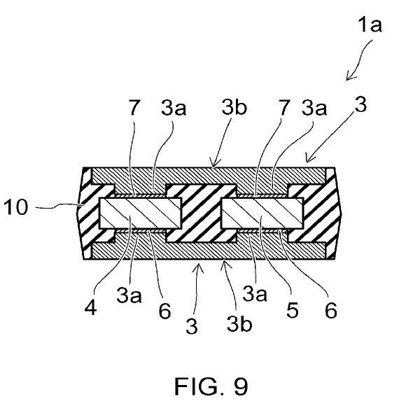

FIG. 9 is a schematic sectional view which illustrates a semiconductor device according to another embodiment. As shown in FIG. 9, in a semiconductor device 1a, an electrode 3 which are similar to that shown in FIGS. 5A, 5B or FIGS. 6A, 6B is provided in place of the electrode 2 shown in the figures. According to such a structure, even if the semiconductor device 1 a faces to a substrate 101 in a contrary direction, a similar heat-dissipation can be performed and uniformity of temperature distribution can be obtained in a semiconductor module 100.

The above embodiments use a semiconductor device which has a switching element and a rectifying element connected in parallel with the switching element. The semiconductor device may have the switching element excluding the rectifying element. In the semiconductor module 100 according to the above first embodiment, two joining portions 105, two joining portions 106 and six semiconductor devices 1 are employed, the numbers of joining portions and semiconductor devices are not limited to these.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. These embodiments may be combined mutually to implement the inventions.

What is claimed is:

1. A semiconductor module, comprising:
a first wiring portion;
a second wiring portion which is provided to oppose the first wiring portion;
a third wiring portion which is provided to oppose the first wiring portion and apart from the second wiring portion;
first semiconductor devices which are provided between the first wiring portion and the second wiring portion and electrically connected with the first wiring portion and the second wiring portion respectively, each of the first semiconductor devices having a first switching element, an input or output terminal of the first switching element being electrically connected with the first wiring portion; and
second semiconductor devices which are provided between the first wiring portion and the third wiring portion and electrically connected with the first wiring portion and the second wiring portion respectively, each of the second semiconductor devices having a second switching element, an output or input terminal of the second switching element being electrically connected with the first wiring portion in a connecting manner contrary to the first switching element.

2. The semiconductor module according to claim 1, further comprising a rectifying element included in each of the first semiconductor devices and connected in parallel with each first switching element, wherein an anode of the rectifying element is electrically connected with the first wiring portion.

3. The semiconductor module according to claim 2, further comprising a rectifying element included in each of the second semiconductor devices and connected in parallel with each second switching element, wherein a cathode of the rectifying element is electrically connected with the first wiring portion.

4. The semiconductor module according to claim 1, further comprising an insulating substrate, wherein the first wiring portion is provided on the insulating substrate and a planar shape of the first wiring portion is the same as that of the substrate.

5. The semiconductor module according to claim 1, wherein the planar shape of the second wiring portion is a rectangle.

6. The semiconductor module according to claim 1, wherein the planar shape of the third wiring portion is a rectangle.

7. The semiconductor module according to claim 1, wherein the planar shapes of the first wiring portion, the second wiring portion, and the third wiring portion are rectangles, and the longitudinal directions of the first wiring portion, the second wiring portion and the third wiring portion are the same approximately.

8. The semiconductor module according to claim 1, further comprising a first lead terminal connected to a control terminal of each first semiconductor device, and a second lead terminal connected to a control terminal of each second semiconductor device, wherein the first lead terminal is bent in a reverse direction to a direction in which the second lead terminal is bent.

9. The semiconductor module according to claim 1, further comprising joining portions which are provided between the first and second semiconductor devices and the first to third wiring portions respectively.

10. The semiconductor module according to claim 1, wherein the first and second switching elements are a bipolar transistor or an insulated gate bipolar transistor, and the input terminal and the output terminal are an emitter and a collector respectively.

11. A semiconductor device, comprising:
a first electrode;
a second electrode which is provided to oppose the first electrode;
a switching element which is provided between the first electrode and the second electrode and is electrically connected to the first electrode and the second electrode;
a rectifying element which is provided between the first electrode and the second electrode and is electrically connected with the first electrode and the second electrode to be connected in parallel with the switching element;
a sealing portion which seals between the first electrode and the second electrode; and
a lead terminal which is connected to a control terminal of the switching element, one end portion of the lead terminal is held in the sealing portion at an approximately central position of the sealing portion in a thickness direction of the sealing portion.

12. The semiconductor device according to claim 11, wherein at least one of the first electrode and the second electrode has a convex portion projected toward the switching element.

13. The semiconductor device according to claim 11, wherein the switching element is a bipolar transistor or an insulated gate bipolar transistor, and an input terminal and an output terminal of the switching element are an emitter and a collector respectively.

14. A semiconductor module, comprising:
a first wiring portion;
a second wiring portion which is provided to oppose the first wiring portion;
a third wiring portion which is provided to oppose the first wiring portion and apart from the second wiring portion;
first semiconductor devices which are provided between the first wiring portion and the second wiring portion and electrically connected with the first wiring portion and the second wiring portion respectively, each of the first semiconductor devices having a first switching element, an input or output terminal of the first switching element being electrically connected with the first wiring portion; and
second semiconductor devices which are provided between the first wiring portion and the third wiring portion and electrically connected with the first wiring portion and the second wiring portion respectively, each of the second semiconductor devices having a second switching element, an output or input terminal of the second switching element being electrically connected with the first wiring portion in a connecting manner contrary to the first switching element, wherein each of the first semiconductor device and the second semiconductor device further including
a first electrode, and a second electrode which is provided to oppose the first electrode, the first electrode and the second electrode sandwiching each of the first and second switching elements, the first and second switching elements being electrically connected to the first electrode and the second electrode,
a rectifying element which is provided between the first electrode and the second electrode and is electrically connected with the first electrode and the second electrode to be connected in parallel with each of the first and second switching elements,
a sealing portion which seals between the first electrode and the second electrode, and
a lead terminal which is connected to a control terminal of each of the first and second switching elements, one end portion of the lead terminal is held in the sealing portion at an approximately central position of the sealing portion in a thickness direction of the sealing portion.

15. The semiconductor device according to claim 14, wherein at least one of the first electrode and the second electrode has a convex portion projected toward each of the first and second switching elements.

16. The semiconductor module according to claim 14, wherein the planar shapes of the first wiring portion, the second wiring portion and the third wiring portion are rectangles, and the longitudinal directions of the first wiring portion, the second wiring portion and the third wiring portion are the same approximately.

17. The semiconductor module according to claim 14, wherein the first lead terminal connected to the control terminal of the first switching element is bent in a reverse direction to a direction in which the second lead terminal connected to the control terminal of the second switching element is bent.
